(19) United States
(12) Patent Application Publication
(10) Pub. No.: US 2007/0166134 A1
(43) Pub. Date: Jul. 19, 2007

(54) Substrate transfer method, substrate transfer apparatus and exposure apparatus

(76) Inventor: Motoko Suzuki, Fukaya-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/637,181

(22) Filed: Dec. 12, 2006

(30) Foreign Application Priority Data
Dec. 20, 2005 (JP) 2005-366813

(51) Int. Cl. H01L 21/677

(52) U.S. Cl. 414/217

(57) ABSTRACT

The present invention relates to a substrate transporting method that transports substrates such as wafers or reticles, a substrate transport apparatus, and an exposure apparatus for use in lithography of, for example, semiconductor integrated circuits, and it is an object of the present invention to efficiently heat a substrate. Furthermore, a substrate transporting method that, after transporting a substrate disposed in the ambient atmosphere into a vacuum chamber and drawing a vacuum therein, transports the substrate to a stage apparatus disposed in a vacuum atmosphere, comprises the step of: transporting the substrate, which is disposed in the ambient atmosphere, to the stage apparatus in a state wherein the substrate is held by a holding means, which can regulate the temperature of the substrate.

### FIELD OF THE INVENTION

The present invention relates to a substrate transporting method that transports substrates such as wafers or reticles, a substrate transport apparatus, and an exposure apparatus for use in lithography of, for example, semiconductor integrated circuits. The present invention more particularly relates to an exposure apparatus that uses, for example, X-rays or a charged particle beam, such as an electron beam or an ion beam, to perform exposure in a vacuum.

### BACKGROUND OF THE INVENTION

In an apparatus, such as an electron beam exposure apparatus, that performs exposure in a vacuum atmosphere, a load chamber or a chamber called a load lock chamber is provided between the exposure apparatus main body and a preprocessing apparatus, such as a prealigner. A vacuum pump is provided to the load lock chamber as an accessory so that a vacuum can be drawn in the chamber. With a load lock chamber, masks (reticles), wafers (sensitive substrates), or the like are received from the preprocessing apparatus under normal pressure and a vacuum is drawn inside the chamber, after which they are transported to the inside of the exposure apparatus.

Furthermore, when evacuating the load lock chamber in such an operation, the temperature of the masks or the wafers therein drops to approximately 2°-4° C. due to the adiabatic expansion of a gas. When the temperature drops in this manner, there are cases wherein the masks, the wafers, or the like warp due to the change in temperature. For example, with a silicon wafer that has a diameter of 200 mm, a 1° C. temperature change causes a dimensional change of approximately 0.5 μm. Thus, if the dimensions of the masks or wafers change, the dimensions of the patterns will change, which makes it impossible to obtain highly accurate patterns. Accordingly, it is necessary, for example, to stand by for several tens of minutes until the temperature rises to its original value and to perform realignment any number of times before performing the exposure.

An exposure apparatus that solves such problems is conventionally known in the art as disclosed in, for example, Japanese Published Unexamined Patent Application No. 2003-234268, wherein, prior to evacuating a load lock chamber, the temperature of masks, wafers, or the like is pre-raised by heating them with a heating wire, which is embedded in a robot arm.

Patent Document 1

Japanese Published Unexamined Patent Application No. 2003-234268

### DISCLOSURE OF THE INVENTION

Problems Solved by the Invention

Nevertheless, because the exposure apparatus discussed above heats substrates, such as masks or wafers, with a heating wire that is embedded in a robot arm, there is a problem in that the substrates cannot be heated when they are not being transported by the robot arm, which makes it difficult to heat the substrates efficiently.

The present invention considers the problems of the conventional art, and it is an object of the present invention to provide a substrate transporting method and a substrate transport apparatus that can efficiently heat substrates. It is another object of the present invention to provide an exposure apparatus that uses this substrate transport apparatus.

Means for Solving the Problems

A substrate transporting method according to a first aspect of the invention is a substrate transporting method that, after transporting a substrate disposed in the ambient atmosphere into a vacuum chamber and drawing a vacuum therein, transports the substrate to a stage apparatus disposed in a vacuum atmosphere, comprising the step of: transporting the substrate, which is disposed in the ambient atmosphere, to the stage apparatus in a state wherein the substrate is held by a holding means, which can regulate the temperature of the substrate.

A substrate transporting method according to a second aspect of the invention is a substrate transporting method according to the first aspect of the invention, wherein the holding means sets a first temperature so that, when the temperature of the substrate is raised to the first temperature before drawing a vacuum around the substrate, and, after drawing a vacuum around the substrate, is subsequently raised to a target temperature, the substrate temperature when it drops is lower than the target temperature.

A substrate transporting method according to a third aspect of the invention is a substrate transporting method according to the first aspect of the invention, wherein the holding means is detachable from the stage apparatus.

A substrate transport apparatus according to a fourth aspect of the invention is a substrate transport apparatus that, after transporting a substrate disposed in the ambient atmosphere, into a vacuum chamber and drawing a vacuum therein, transports the substrate to a stage apparatus disposed in a vacuum atmosphere, comprising: a holding means that holds the substrate; and a transporting means that transports the substrate, which is disposed in the ambient atmosphere, to the stage apparatus in a state wherein the substrate is held by the holding means; wherein, the holding means comprises a temperature regulating means that regulates the temperature of the substrate.

A substrate transport apparatus according to a fifth aspect of the invention is a substrate transport apparatus according to the fourth aspect of the invention, wherein: the temperature regulating means sets a first temperature so that, when the temperature of the substrate is raised to the first temperature before drawing a vacuum around the substrate, and, after drawing a vacuum around the substrate, is subsequently raised to a target temperature, the substrate temperature when it drops is lower than the target temperature.

A substrate transport apparatus according to a sixth aspect of the invention is a substrate transport apparatus according to the fourth aspect of the invention, wherein the holding means is detachable from the stage apparatus.

A substrate transport apparatus according to a seventh aspect of the invention is a substrate transport apparatus according to the fourth aspect of the invention, wherein the holding means comprises: an electrostatic chuck that detachably holds the substrate; and a power supplying means that supplies electric power to the electrostatic chuck.

A substrate transport apparatus according to an eighth aspect of the invention is a substrate transport apparatus according to the fourth aspect of the invention, wherein the temperature regulating means comprises: an electric heater that heats the substrate; a temperature sensor that detects the temperature of the substrate; a controlling means that controls the temperature of the substrate based on a signal from the temperature sensor; and a power supplying means that supplies electric power to the electric heater.

A substrate transport apparatus according to a ninth aspect of the invention is a substrate transport apparatus according to the seventh aspect of the invention, wherein the power supplying means is a storage battery that is disposed in the electrostatic chuck.

A substrate transport apparatus according to a tenth aspect of the invention is a substrate transport apparatus according to the ninth aspect of the invention, comprising a charging means for charging the storage battery.

A substrate transport apparatus according to an eleventh aspect of the invention is a substrate transport apparatus according to the fourth aspect of the invention, wherein the substrate is exposed while it is held by the holding means as is.

A substrate transport apparatus according to a twelfth aspect of the invention is a substrate transport apparatus according to the fourth aspect of the invention, wherein with the substrate held by the holding means as is after the exposure is complete, the substrate is transported to the location where it was transferred in order to be held by the holding means.

A substrate transport apparatus according to a thirteenth aspect of the invention is a substrate transport apparatus according to the fourth aspect of the invention, wherein the transporting means, which transfers the substrate to the holding means, is used to transfer the holding means at least in one part of the section through which it is transported.

An exposure apparatus according to a fourteenth aspect of the invention comprises: an illumination optical system; a stage apparatus, which is disposed inside a vacuum apparatus; a transport robot that transports a substrate to a holding means, which adjusts the temperature of the substrate; a transport robot that transports the holding means, whereon the substrate is mounted, to the stage apparatus, which is disposed inside a vacuum atmosphere; and a temperature regulating means that regulates the temperature of the substrate.

An exposure apparatus according to a fifteenth aspect of the invention is an exposure apparatus according to the fourteenth aspect of the invention, wherein the holding means comprises: an electrostatic chuck that detachably holds the substrate; and a power supplying means that supplies electric power to the electrostatic chuck.

An exposure apparatus according to a sixteenth aspect of the invention is an exposure apparatus according to the fourteenth aspect of the invention, wherein the temperature regulating means comprises: an electric heater that heats the substrate; a temperature sensor that detects the temperature of the substrate; a controlling means that controls the temperature of the substrate based on a signal from the temperature sensor; and a power supplying means that supplies electric power to the electric heater.

Effects of the Invention

The substrate transporting method and the substrate transport apparatus of the present invention can efficiently heat substrates.

The exposure apparatus of the present invention can improve throughput by reducing the time that substrate temperature is controlled.

### BRIEF DESCRIPTION OF THE DRAWINGS

FIG. 1 is an explanatory diagram that shows an exposure apparatus wherein one embodiment of a substrate transport apparatus of the present invention is provided.

FIG. 2 is an explanatory diagram that shows the details of a wafer holder shown in FIG. 1.

FIG. 3 is an explanatory diagram that shows wafer temperature control, which is performed by a CPU.

FIG. 4 is an explanatory diagram that shows the details of an optical system of the exposure apparatus shown in FIG. 1.

### DETAILED DESCRIPTION OF THE PREFERRED EMBODIMENTS

The following explains the details of the embodiments of the present invention, referencing the drawings.

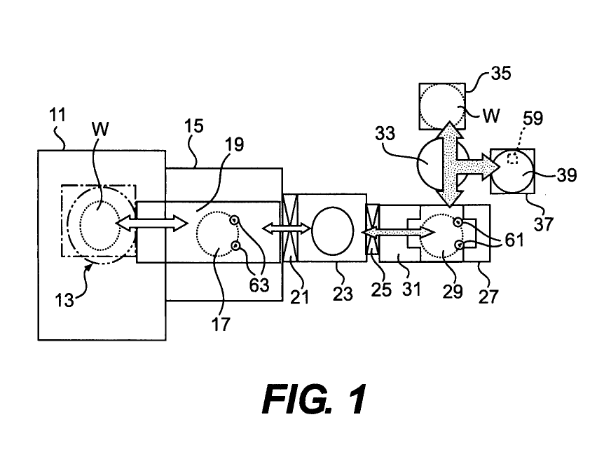

FIG. 1 is a plan view that schematically shows an exposure apparatus wherein one embodiment of a substrate transport apparatus of the present invention is provided.

With the present exposure apparatus, a wafer stage 13 is disposed in a wafer stage chamber 11. A wafer prealignment chamber 15 is coupled to the wafer stage chamber 11. A wafer prealigner 17 and a vacuum robot arm 19 are disposed in the wafer prealignment chamber 15.

A load lock chamber 23 is coupled to the wafer prealignment chamber 15 via a gate valve 21. A wafer prealignment chamber 27 is coupled to the load lock chamber 23 via a gate valve 25. The wafer prealignment chamber 27 is open to the ambient atmosphere. A vacuum pump (not shown) is provided to the load lock chamber 23 in order to draw a vacuum inside the chamber.

A wafer prealigner 29 is disposed in the wafer prealignment chamber 27. In addition, an ambient atmosphere robot arm 31 is disposed between the wafer prealigner 29 and the gate valve 25. An ambient atmosphere robot arm 33 is disposed on the outer side of the wafer prealignment chamber 27. A wafer cassette 35 and a wafer holder detachable stocker 37 are disposed on the outer side of the ambient atmosphere robot arm 33.

With the present embodiment, a wafer holder 39 is housed in the wafer holder detachable stocker 37. Furthermore, the transport and exposure of a wafer W are performed in a state wherein the wafer W is continuously held by the wafer holder 39.

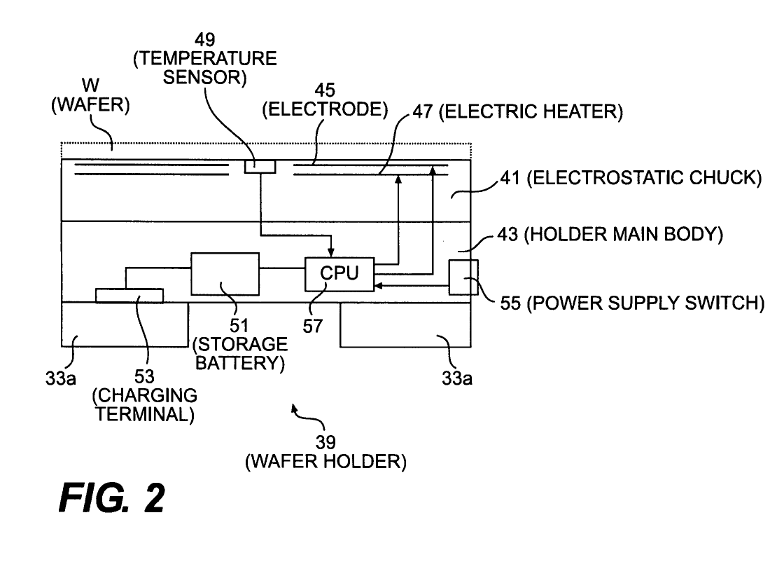

FIG. 2 shows a detailed cross sectional view of the wafer holder 39.

The wafer holder 39 comprises an electrostatic chuck 41 and a holder main body 43. The electrostatic chuck 41 is joined to an upper surface of the wafer holder 39.

The electrostatic chuck 41 comprises an electrode 45, an electric heater 47, and a temperature sensor 49. The electrode 45 generates static electricity for chucking the wafer W. The electric heater 47 heats the wafer W. The temperature sensor 49 measures the temperature of the wafer W.

The holder main body 43 comprises a storage battery 51, a charging terminal 53, a power supply switch 55, and a CPU 57. The storage battery 51 supplies the electricity that is needed inside the wafer holder 39. The charging terminal 53 is connected to the storage battery 51 and charges such with electricity that is supplied from an external power supply terminal, which is discussed later. Turning the power supply switch 55 on and off turns the CPU 57 on and off. In a state wherein the power supply switch 55 is turned on, an urging means (not shown) projects the power supply switch 55 from the holder main body 43. Furthermore, the power supply switch 55 transitions back to the off state if pressed.

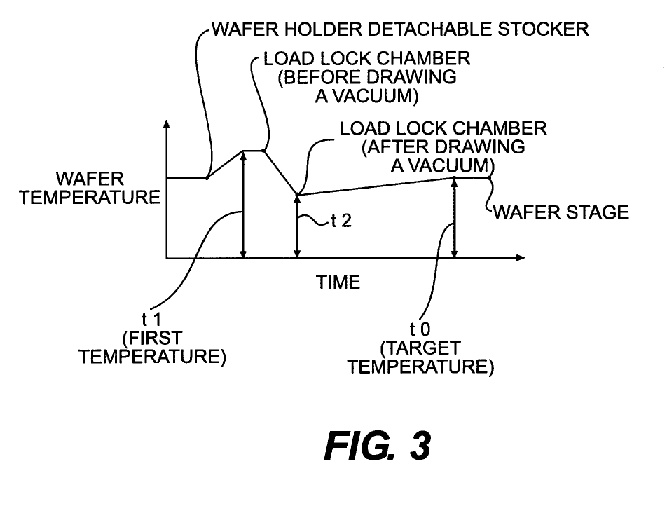

Turning the power supply switch 55 on starts the operation of the CPU 57, which controls the operation of the wafer holder 39. Namely, when the power supply switch 55 is turned on, the CPU 57 impresses a prescribed voltage to the electrode 45 in order to chuck the wafer W to the electrostatic chuck 41. Furthermore, turning the power supply switch 55 off terminates the impression of the voltage on the electrode 45. In addition, a temperature signal from the temperature sensor 49 is input to the CPU 57, which controls the temperature of the wafer W as shown in FIG. 3 by turning the electric heater 47 on and off based on this temperature signal.

With the exposure apparatus discussed above, the transport of the wafer W to the inside of the wafer stage chamber 11 is performed as discussed below. The transport is performed in a state wherein the wafer W is continuously held by the wafer holder 39.

First, the ambient atmosphere robot arm 33 retrieves one of a plurality of wafers W that is inside the wafer cassette 35 and transports it to the wafer holder detachable stocker 37. The wafer holder 39 is housed inside the wafer holder detachable stocker 37. In this housed state, the power supply switch 55 of the wafer holder 39 is pressed by the inner surface of the wafer holder detachable stocker 37, and the power supply switch 55 thereby transitions to the off state. In addition, the storage battery 51 of the wafer holder 39 is precharged. In the present embodiment, an external power supply terminal 59, which is connected to the charging terminal 53 of the wafer holder 39, is provided to the wafer holder detachable stocker 37. Thus, by housing the wafer holder 39 in the wafer holder detachable stocker 37, the storage battery 51 is charged automatically.

Next, the ambient atmosphere robot arm 33 mounts the wafer W on the upper surface of the electrostatic chuck 41 of the wafer holder 39. Furthermore, an arm bar 33a (refer to FIG. 2) of the ambient atmosphere robot arm 33 lifts the wafer holder 39, whereupon the pressing of the power supply switch 55 by the wafer holder detachable stocker 37 is released and the power supply switch 55 is thereby turned on.

When the power supply switch 55 transitions to the on state, the operation of the CPU 57 starts. Thereby, a voltage is impressed upon the electrode 45, which chucks the wafer W to the electrostatic chuck 41. In addition, the temperature signal from the temperature sensor 49 is input to the CPU 57, which controls the temperature of the wafer W as shown in FIG. 3 by turning the electric heater 47 on and off based on this temperature signal. Furthermore, the relevant details are discussed later.

Next, the ambient atmosphere robot arm 33 retrieves the wafer holder 39 inside the wafer holder detachable stocker 37 and transports it to the wafer prealigner 29. At the wafer prealigner 29, a detector 61 detects a mark (notch) for aligning the wafer W. Furthermore, the wafer holder 39 is aligned so that the alignment mark is at a prescribed position.

After alignment is complete, the ambient atmosphere robot arm 31 retrieves the wafer holder 39. Furthermore, the gate valve 25 of the load lock chamber 23 opens and the ambient atmosphere robot arm 31 transports the wafer holder 39 to the inside of the load lock chamber 23.

Moreover, with the present embodiment, the CPU 57 heats the wafer W as shown in FIG. 3 by energizing the electric heater 47 of the wafer holder 39 while the wafer holder 39 is transported from the wafer holder detachable stocker 37 to the inside of the load lock chamber 23. Furthermore, the relevant details are discussed later.

Because the wafer W is heated as discussed above, the temperature of the wafer W, which was transported to the load lock chamber 23, rises just to a prescribed temperature. Thereafter, the gate valve 25 closes and a vacuum is drawn until the interior of the load lock chamber 23 reaches a target degree of vacuum. When the load lock chamber 23 is evacuated, the temperature of the wafer W drops as shown in FIG. 3. Furthermore, the hatched arrows in the figure indicate the movement pathways of the ambient atmosphere robot arms 33, 31.

When the interior of the load lock chamber 23 reaches the prescribed degree of vacuum, the gate valve 21 between the load lock chamber 23 and the wafer prealignment chamber 15 opens. Furthermore, the vacuum robot arm 19, which is provided to the wafer prealignment chamber 15, retrieves the wafer holder 39 from the load lock chamber 23. The retrieved wafer holder 39 is transported to the wafer prealigner 17, after which the gate valve 21 is closed. At the wafer prealigner 17, a detector 63 thereof detects the mark (notch) for aligning the wafer W. Furthermore, the wafer holder 39 is aligned so that the alignment mark coincides with a prescribed position.

When the alignment of the wafer holder 39 is complete, the vacuum robot arm 19 transports the wafer holder 39 from the wafer prealignment chamber 15 to the wafer stage chamber 11. A holding member (not shown), such as an electrostatic chuck, is provided to the wafer stage 13 inside the wafer stage chamber 11, and the wafer W is fixed to the holding member (not shown) along with the wafer holder 39. Furthermore, the outline arrows in the figure indicate the movement pathways of the vacuum robot arm 19.

Furthermore, the wafer W is aligned in this state and then exposed. After exposure is complete, the wafer W and the wafer holder 39 are transported to the wafer holder detachable stocker 37 in the reverse direction of the movement pathways, and the wafer W is housed in the wafer cassette 35, thus completing the sequence of the operation.

FIG. 3 schematically shows the relationship between time and the temperature of the wafer W when the wafer holder 39 is transported in a state wherein it is holding the wafer W.

When the wafer holder 39, whereon the wafer W is mounted, is lifted from the wafer holder detachable stocker 37, the power supply switch 55 is turned on and the CPU 57 starts temperature control of the wafer W. First, the CPU 57 heats the wafer W by turning the electric heater 47 on. A signal from the temperature sensor 49 is input to the CPU 57, which turns the electric heater 47 off when the temperature of the wafer W that is detected by the temperature sensor 49 reaches a first temperature t1.

Thereafter, the wafer W is transported to the load lock chamber 23 and, when a vacuum is drawn inside the load lock chamber 23, the temperature of the wafer W drops due to adiabatic cooling and reaches a temperature t2 that is slightly lower than a target temperature t0. When the temperature of the wafer W detected by the temperature sensor 49 has stopped falling, the CPU 57 once again heats the wafer W by turning the electric heater 47 on at temperature t2, which is. Furthermore, when the temperature of the wafer W detected by the temperature sensor 49 reaches the target temperature t0, the CPU 57 turns the electric heater 47 off.

The first temperature t1 discussed above is preset in the CPU 57 based on the relationship between the ultimate target temperature t0 of the wafer W and a predicted value, which is previously derived, of the wafer W temperature drop that is caused by the drawing of a vacuum in the load lock chamber 23. In the present embodiment, the first temperature t1 is set to a temperature so as to ensure that the temperature that is expected at the point in time when the temperature of the wafer W drops as a result of the drawing of a vacuum inside the vacuum chamber is slightly lower than the target temperature t0. Setting the first temperature t1 to such a temperature makes it possible to bring the temperature of the wafer W to the target temperature t0 by heating the wafer W once again using the electric heater 47 in a state wherein the wafer W is disposed in a vacuum by the load lock chamber 23. Accordingly, it is possible to control the temperature of the wafer W by using just the electric heater 47.

With the substrate transport apparatus discussed above, the wafer W, which is disposed in the ambient atmosphere, is transported to the wafer stage 13 in a state wherein the wafer W is held by the wafer holder 39, which can regulate the temperature of the wafer W; therefore, it is possible to heat the wafer W at an arbitrary position while it is being transported to the wafer stage 13, and thereby to heat the wafer W efficiently.

In addition, because the wafer holder 39 is detachable from the wafer stage 13, if particles adhere to the wafer holder 39, it is possible to easily and reliably clean it by detaching it from the wafer holder detachable stocker 37. Furthermore, a plurality of wafer holders 39 is available. Accordingly, it is also possible to transport a plurality of wafers W and to immediately replace a wafer holder 39 should it become contaminated.

### Details of the Exposure Apparatus

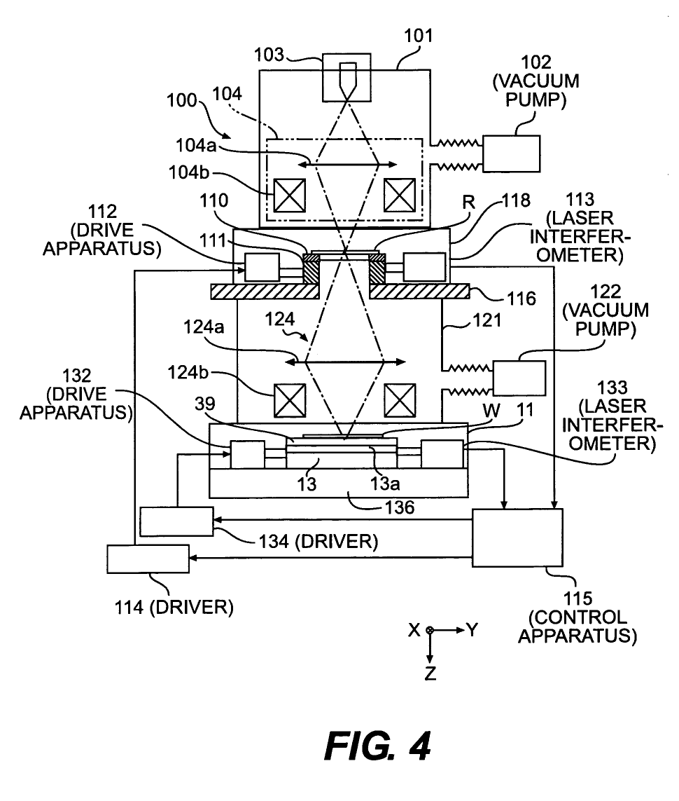

FIG. 4 shows the details of an optical system of the exposure apparatus discussed above. This exposure apparatus is a charged particle beam (electron beam) exposure apparatus.

With the present exposure apparatus, an illumination optical system lens barrel 101 is disposed at the upper part of an exposure apparatus 100. A vacuum pump 102 is connected to this illumination optical system lens barrel 101 and evacuates such. An electron gun 103 is disposed at the upper part of the illumination optical system lens barrel 101 and radiates an electron beam downward. A condenser lens 104a and an electron beam deflector 104b, which constitute an illumination optical system 104, are disposed below the electron gun 103. Furthermore, the condenser lens 104a in the figure is one stage, but the illumination optical system is actually provided with, for example, multiple stages of lenses and beam forming apertures.

A reticle chamber 118, which is mounted on a base plate 116, is disposed at a lower part of the illumination optical system lens barrel 101. A vacuum pump (not shown) evacuates the reticle chamber 118. A reticle stage 111 is disposed on the base plate 116 inside the reticle chamber 118. A reticle R is fixed by, for example, electrostatically chucking it to a chuck 110, which is provided at the upper part of the reticle stage 111. A drive apparatus 112, which is shown on the left side in the figure, is connected to the reticle stage 111. Furthermore, the actual drive apparatus 112 is incorporated in the reticle stage 111. The drive apparatus 112 is connected to a control apparatus 115 via a driver 114.

A laser interferometer 113, which is shown on the right side in the figure, is provided to the reticle stage 111 as an accessory. The laser interferometer 113 is connected to the control apparatus 115. When the positional information of the reticle stage 111, which is measured by the laser interferometer 113, is input to the control apparatus 115, a command is sent from the control apparatus 115 to the driver 114, which drives the drive apparatus 112, in order to set the position of the reticle stage 111 at the target position. As a result, it is possible to reliably perform feedback control of the position of the reticle stage 111 in real time.

The electron beam that is radiated from the electron gun 103 of the illumination optical system lens barrel 101 is converged by the condenser lens 104a. Continuing, successive scans by the deflector 104b in the transverse direction of the figure illuminates each subfield of the reticle R, which is chucked on the reticle stage 111 inside the reticle chamber 118 (in the visual field of the optical system).

A projection optical system lens barrel 121 is disposed on the lower surface side of the base plate 116. A vacuum pump 122 is connected to the projection optical system lens barrel 121 and evacuates such. A projection optical system 124, which includes a condenser lens (projection lens) 124a and a deflector 124b, and the wafer W are disposed inside the projection optical system lens barrel 121. Furthermore, the condenser lens 124a in the figure is one stage, but the actual projection optical system 124 is provided with multiple stages of lenses, aberration correcting lenses, coils, and the like.

The wafer stage chamber 11, which is mounted on a base plate 136, is disposed at the lower part of the projection optical system lens barrel 121. A vacuum pump (not shown) evacuates the wafer stage chamber 11. The wafer stage 13 is disposed on the base plate 136 inside the wafer stage chamber 11.

The wafer holder 39 (discussed above), which holds the wafer W, is fixed by electrostatically chucking it to an electrostatic chuck 13a, which is provided to the upper part of the wafer stage 13. A drive apparatus 132, which is shown on the left side of the figure, is connected to the wafer stage 13. Furthermore, the actual drive apparatus 132 is incorporated inside the wafer stage 13. The drive apparatus 132 is connected to the control apparatus 115 via a driver 134.

A laser interferometer 133, which is shown on the right side of the figure, is provided to the wafer stage 13 as an accessory. The laser interferometer 133 is connected to the control apparatus 115. When the positional information of the wafer stage 13, which is measured by the laser interferometer 133, is input to the control apparatus 115, a command is sent from the control apparatus 115 to the driver 134, which drives the drive apparatus 132, in order to set the position of the wafer stage 13 at the target position. As a result, it is possible to reliably perform feedback control of the position of the wafer stage 13 in real time.

The electron beam, which passes through the reticle R on the reticle stage 111 inside the reticle chamber 118, is converged by the condenser lens 124a inside the projection optical system lens barrel 121. The electron beam, which passes through the condenser lens 124a, is deflected by the deflector 124b and an image of the reticle R is formed at a prescribed position on the wafer W. Thereby, the wafer W is exposed.

### Supplementary Points Concerning the Embodiments

The above explained the present invention based on the embodiments discussed above, but the technical scope of the present invention is not limited to those embodiments and may encompass, for example, the following types of modes.

(1) The embodiments discussed above explained an example wherein the present invention is adapted to the transport of a wafer W, but the present invention can be widely adapted to the transport of substrates such as reticles (masks).

(2) The embodiments discussed above explained an example wherein the temperature of the wafer W is controlled by use of the electric heater 47, which is disposed in the wafer holder 39; however, for example, a passageway for a refrigerant, such as a liquid, may be provided to the wafer holder and the wafer temperature may be controlled by use of the refrigerant.

(3) The embodiments discussed above explained an example wherein the temperature of the wafer W is controlled by heating it; however, the temperature of the wafer can be more reliably regulated by, for example, providing a heating means that heats the wafer and a cooling means to the holder main body.

(4) The embodiments discussed above explained an example wherein the temperature of the wafer W is controlled by turning the electric heater 47 on and off, but the temperature may be controlled by controlling the value of the electric current flowing through the electric heater.

(5) The embodiments discussed above explained an example wherein the wafer W is transported along with the wafer holder 39 from the wafer holder detachable stocker 37 to the wafer stage 13; however, if there is a temperature differential between the exposure apparatus and inline equipment, which performs various processes, then the present invention can also be adapted to the transport of the wafer W from the inline equipment.

(6) The embodiments discussed above explained an example wherein the present invention is adapted to a charged particle beam exposure apparatus, but the present invention can be widely adapted to exposure apparatuses that perform exposure with the substrate, such as the wafer W or the reticle, contained in a vacuum atmosphere.

(7) The embodiments discussed above explained an example wherein the wafer W is transported along with the wafer holder 39 from the wafer holder detachable stocker 37 to the wafer stage 13; however, the wafer holder detachable stocker 37 does not necessarily need to be in the ambient atmosphere, and may be disposed in a vacuum. In this case, the temperature of the wafer W and the wafer holder 39 is regulated only in a vacuum.

(8) The embodiments discussed above perform charging at the wafer holder detachable stocker 37, but charging does not necessarily need to be performed there. For example, charging may be performed on the prealigner.

(9) The embodiments discussed above describe an example wherein the temperature of the wafer W is controlled by controlling the on/off states of the electric heater 47; however, a Peltier element may be used and the temperature may be controlled using not only heating, but also cooling.

1. A substrate transporting method that, after transporting a substrate disposed in the ambient atmosphere into a vacuum chamber and drawing a vacuum therein, transports the substrate to a stage apparatus disposed in a vacuum atmosphere, comprising the step of:
transporting the substrate, which is disposed in the ambient atmosphere, to the stage apparatus in a state wherein the substrate is held by a holding means, which can regulate the temperature of the substrate in at least one part of the section through which it is transported.

2. A substrate transporting method according to claim 1, wherein
the holding means sets a first temperature so that, when the temperature of the substrate is raised to the first temperature before drawing a vacuum around the substrate, and, after drawing a vacuum around the substrate, is subsequently raised to a target temperature, the substrate temperature when it drops is lower than the target temperature.

3. A substrate transporting method according to claim 1, wherein
the holding means is detachable from the stage apparatus.

4. A substrate transport apparatus that, after transporting a substrate disposed in the ambient atmosphere, into a vacuum chamber and drawing a vacuum therein, transports the substrate to a stage apparatus disposed in a vacuum atmosphere, comprising:
a holding means that holds the substrate; and
a transporting means that transports the substrate, which is disposed in the ambient atmosphere, to the stage apparatus in a state wherein the substrate is held by the holding means;
wherein,
the holding means comprises a temperature regulating means that regulates the temperature of the substrate.

5. A substrate transport apparatus according to claim 4, wherein:
the temperature regulating means sets a first temperature so that, when the temperature of the substrate is raised to the first temperature before drawing a vacuum around the substrate, and, after drawing a vacuum around the substrate, is subsequently raised to a target temperature, the substrate temperature when it drops is lower than the target temperature.

6. A substrate transport apparatus according to claim 4, wherein
the holding means is detachable from the stage apparatus.

7. A substrate transport apparatus according to claim 4, wherein
the holding means comprises:
an electrostatic chuck that detachably holds the substrate; and
a power supplying means that supplies electric power to the electrostatic chuck.

8. A substrate transport apparatus according to claim 4, wherein
the temperature regulating means comprises:
an electric heater that heats the substrate;
a temperature sensor that detects the temperature of the substrate;
a controlling means that controls the temperature of the substrate based on a signal from the temperature sensor; and
a power supplying means that supplies electric power to the electric heater.

9. A substrate transport apparatus according to claim 7, wherein
the power supplying means is a storage battery that is disposed in the electrostatic chuck.

10. A substrate transport apparatus according to claim 9, comprising:
a charging means for charging the storage battery.

11. A substrate transport apparatus according to claim 4, wherein
the substrate is exposed while it is held by the holding means as is.

12. A substrate transport apparatus according to claim 4, wherein
with the substrate held by the holding means as is after the exposure is complete, the substrate is transported to the location where it was transferred in order to be held by the holding means.

13. A substrate transport apparatus according to claim 4, wherein
the transporting means, which transfers the substrate to the holding means, is used to transfer the holding means at least in one part of the section through which it is transported.

14. An exposure apparatus, comprising:
an illumination optical system;
a stage apparatus, which is disposed inside a vacuum apparatus;
a transport robot that transports a substrate to a holding means, which adjusts the temperature of the substrate;
a transport robot that transports the holding means, whereon the substrate is mounted, to the stage apparatus, which is disposed inside a vacuum atmosphere; and
a temperature regulating means that regulates the temperature of the substrate.

15. An exposure apparatus according to claim 14, wherein
the holding means comprises:
an electrostatic chuck that detachably holds the substrate; and
a power supplying means that supplies electric power to the electrostatic chuck.

16. An exposure apparatus according to claim 14, wherein
the temperature regulating means comprises:
an electric heater that heats the substrate;
a temperature sensor that detects the temperature of the substrate;
a controlling means that controls the temperature of the substrate based on a signal from the temperature sensor; and
a power supplying means that supplies electric power to the electric heater.
